(19) United States
(12) Patent Application Publication
(10) Pub. No.: US 2021/0124215 A1
(43) Pub. Date: Apr. 29, 2021

(54) BACKLIGHT SOURCE MANUFACTURING METHOD, BACKLIGHT SOURCE, AND DISPLAY APPARATUS

(71) Applicant: BOE Technology Group Co., Ltd., Beijing (CN)

(72) Inventors: Shengguang Ban, Beijing (CN); Zhanfeng Cao, Beijing (CN); Ke Wang, Beijing (CN); Qingzhao Liu, Beijing (CN); Shuilang Dong, Beijing (CN); Song Liu, Beijing (CN)

(73) Assignee: BOE TECHNOLOGY GROUP CO., LTD.

(21) Appl. No.: 16/918,080

(22) Filed: Jul. 1, 2020

(30) Foreign Application Priority Data
Oct. 28, 2019 (CN) 201911033345.6

(51) Int. Cl. G02F 1/13357; H01L 27/15; H01L 33/26

(52) U.S. Cl. CPC G02F 1/133603; G02F 2001/133612; H01L 33/26; H01L 27/153

(57) ABSTRACT

The present disclosure provides a backlight source. The backlight source includes: a substrate, and a first conductive structure, a plurality of light emitting units, and a second conductive structure which are stacked on the substrate. The first conductive structure and the second conductive structure are respectively on two sides of the plurality of light emitting units in a direction perpendicular to the substrate, and the first conductive structure and the second conductive structure are configured to load a voltage for the plurality of light emitting units.

This application claims priority to Chinese Patent Application No. 201911033345.6, filed on Oct. 28, 2019, and entitled “BACKLIGHT SOURCE MANUFACTURING METHOD, BACKLIGHT SOURCE, AND DISPLAY APPARATUS”, the entire contents of which are incorporated herein by reference.

### TECHNICAL FIELD

The present disclosure relates to the field of display technologies, and in particular, to a backlight source manufacturing method, a backlight source, and a display apparatus.

### BACKGROUND

Currently, in a display apparatus using a display panel that cannot self-illuminate, such as a liquid crystal panel, a backlight source is further disposed to cooperate with the display panel to achieve a display function.

A display apparatus is provided, including a display panel and a backlight source. The backlight source includes a substrate. An anode cable and a cathode cable are disposed on the substrate. A plurality of light emitting units are disposed on either of the anode cable and the cathode cable. The plurality of light emitting units can be driven by the anode cable and the cathode cable to emit light.

### SUMMARY

The present disclosure provides a backlight source manufacturing method, a backlight source, and a display apparatus.

In one aspect, a backlight source is provided. The backlight source includes:

a substrate, and a first conductive structure, a plurality of light emitting units, and a second conductive structure which are stacked on the substrate, wherein the first conductive structure and the second conductive structure are respectively on two sides of the plurality of light emitting units in a direction perpendicular to the substrate, and the first conductive structure and the second conductive structure are configured to load a voltage for the plurality of light emitting units.

Optionally, one of the first conductive structure and the second conductive structure is a conductive layer.

Optionally, at least two light emitting regions are provided on the substrate, and at least two light emitting units are disposed in each light emitting region; and

the first conductive structure includes at least two light emitting unit cables that are in a one-to-one correspondence with the at least two light emitting regions, and each light emitting unit cable is configured to connect light emitting units in a corresponding light emitting region.

Optionally, at least a part of at least one of the first conductive structure and the second conductive structure is out of the light emitting regions.

Optionally, at least one of the first conductive structure and the second conductive structure includes a plurality of electrode cables, and a width of the electrode cable is greater than a width of the light emitting unit cable.

Optionally, the backlight source includes an insulating layer between the plurality of light emitting units and the second conductive structure.

Optionally, the second conductive structure is a cathode conductive layer.

Optionally, a material of the conductive layer includes indium tin oxide.

Optionally, a material of the conductive layer includes a magnesium-copper alloy.

Optionally, a material of the first conductive structure includes copper.

Optionally, the first conductive structure includes a molybdenum-niobium alloy layer, a copper layer, and another molybdenum-niobium alloy layer which are stacked.

Optionally, the second conductive structure is a cathode conductive layer;

at least two light emitting regions are provided on the substrate, and at least two light emitting units are disposed in each light emitting region;

the first conductive structure includes at least two light emitting unit cables that are in a one-to-one correspondence with the at least two light emitting regions, and each light emitting unit cable is configured to connect light emitting units in a corresponding light emitting region; the first conductive structure includes a plurality of electrode cables, and a width of the electrode cable is greater than a width of the light emitting unit cable;

and at least a part of the electrode cable in the first conductive structure is out of the light emitting regions.

In another aspect, a backlight source manufacturing method is provided. The method includes:

providing a substrate; and

sequentially forming, on the substrate, a first conductive structure, a plurality of light emitting units, and a second conductive structure which are stacked, wherein the first conductive structure and the second conductive structure are respectively on two sides of the plurality of light emitting units in a direction perpendicular to the substrate, and the first conductive structure and the second conductive structure are configured to load a voltage for the plurality of light emitting units.

Optionally, at least two light emitting regions are provided on the substrate, at least two light emitting units are disposed in each light emitting region, the first conductive structure includes a plurality of electrode cables and at least two light emitting unit cables that are in a one-to-one correspondence with the at least two light emitting regions, each light emitting unit cable is configured to connect light emitting units in a corresponding light emitting region, and sequentially forming, on the substrate, a first conductive structure, a plurality of light emitting units, and a second conductive structure which are stacked includes:

forming the at least two light emitting unit cables and the electrode cables in the first conductive structure on the substrate by a patterning process; and

sequentially forming, on the first conductive structure, the plurality of light emitting units and the second conductive structure which are stacked.

Optionally, sequentially forming, on the substrate, a first conductive structure, a plurality of light emitting units, and a second conductive structure which are stacked includes:

sequentially forming, on the substrate, the first conductive structure and the plurality of light emitting units which are stacked; and

sequentially forming, on the plurality of light emitting units, an insulating layer and the second conductive structure which are stacked.

Optionally, sequentially forming, on the substrate, a first conductive structure, a plurality of light emitting units, and a second conductive structure which are stacked includes:

sequentially forming, on the substrate, the first conductive structure, an insulating layer, a reflective layer, the plurality of light emitting units, and the second conductive structure which are stacked.

In another aspect, a display apparatus is provided. The display apparatus includes a display panel and a backlight source, and the backlight source includes a substrate, and a first conductive structure, a plurality of light emitting units, and a second conductive structure which are stacked on the substrate, wherein the first conductive structure and the second conductive structure are respectively on two sides of the plurality of light emitting units in a direction perpendicular to the substrate, and the first conductive structure and the second conductive structure are configured to load a voltage for the plurality of light emitting units.

Optionally, one of the first conductive structure and the second conductive structure is a conductive layer.

Optionally, at least two light emitting regions are provided on the substrate, and at least two light emitting units are disposed in each light emitting region; and

the first conductive structure includes at least two light emitting unit cables that are in a one-to-one correspondence with the at least two light emitting regions, and each light emitting unit cable is configured to connect light emitting units in a corresponding light emitting region.

Optionally, at least a part of at least one of the first conductive structure and the second conductive structure is out of the light emitting regions.

### BRIEF DESCRIPTION OF THE DRAWINGS

FIG. 1 is a schematic diagram of a top view structure of a backlight source;

FIG. 2 is a flowchart of a backlight source manufacturing method according to an embodiment of the present disclosure;

FIG. 3 is another flowchart of a backlight source manufacturing method according to an embodiment of the present disclosure;

FIG. 4 is a schematic diagram of a top view structure of a backlight source manufactured by using the backlight source manufacturing method in FIG. 3;

FIG. 5 is a schematic cross-sectional view of a structure shown in FIG. 4;

FIG. 6 is another schematic structural diagram of a backlight source manufactured by using the backlight source manufacturing method in FIG. 3;

FIG. 7 is another schematic structural diagram of a backlight source manufactured by using the backlight source manufacturing method in FIG. 3;

FIG. 8 is another schematic structural diagram of a backlight source manufactured by using the backlight source manufacturing method in FIG. 3;

FIG. 9 is another schematic structural diagram of a backlight source manufactured by using the backlight source manufacturing method in FIG. 3;

FIG. 10 is another schematic structural diagram of a backlight source manufactured by using the backlight source manufacturing method in FIG. 3;

FIG. 11 is another schematic structural diagram of a backlight source manufactured by using the backlight source manufacturing method in FIG. 3;

FIG. 12 is another flowchart of a backlight source manufacturing method according to an embodiment of the present disclosure;

FIG. 13 is a schematic structural diagram of a backlight source manufactured by using the backlight source manufacturing method in FIG. 12;

FIG. 14 is a diagram of comparing steps in a backlight source manufacturing method and steps in a manufacturing method according to an embodiment of the present disclosure;

FIG. 15 is a schematic diagram of a top view structure of the backlight source shown in FIG. 11; and

FIG. 16 is a schematic diagram of a top view structure of the backlight source shown in FIG. 13.

### DETAILED DESCRIPTION

To make the advantages of the present disclosure clearer, the implementations of the present disclosure are described below in detail with reference to the accompanying drawings.

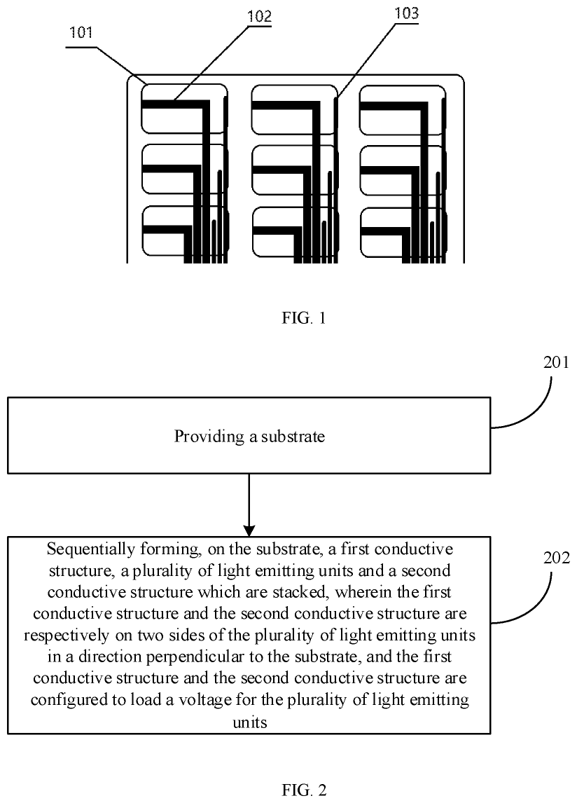

As shown in FIG. 1, in a backlight source having at least two light emitting regions 101, an anode cable 102 and a cathode cable 103 that are configured to drive a light emitting unit (not shown in FIG. 1) in each light emitting region 101 are disposed at a same layer. Most of each of the anode cable 102 and the cathode cable 103 is inside the light emitting region 101. The light emitting unit in the light emitting region 101 may be a light emitting diode (LED). Each light emitting region 101 requires a relatively large driving current. Therefore, when a material is determined, the anode cable 102 and the cathode cable 103 need to have a relatively large cross-sectional area. When there is a relatively large quantity of light emitting regions 101, correspondingly, there are also a relatively large quantity of anode cables 102 and a relatively large quantity of cathode cables 103. In this case, because each light emitting region 101 has a limited internal area, both the anode cable 102 and the cathode cable 103 cannot be set to be relatively wide, and only thicknesses can be increased. However, generally, a cable includes a metal material (for example, metallic copper). Therefore, limited by internal metal stress, a relatively thick cable is difficult to be formed by one patterning process, and can be formed through manufacturing by a plurality of patterning processes, thereby increasing a quantity of patterning processes.

FIG. 2 is a flowchart of a backlight source manufacturing method according to an embodiment of the present disclosure. The method includes the following steps:

In step 201, a substrate is provided.

In step 202, a first conductive structure, a plurality of light emitting units, and a second conductive structure which are stacked are sequentially formed on the substrate. The first conductive structure and the second conductive structure are respectively on two sides of the plurality of light emitting units in a direction perpendicular to the substrate, and the first conductive structure and the second conductive structure are configured to load a voltage for the plurality of light emitting units.

The first conductive structure and the second conductive structure may load a voltage for the plurality of light emitting units, so that the light emitting units emit light. Each of the first conductive structure and the second conductive structure may include electrode cables, and the electrode cables may include a cathode cable and an anode cable.

To sum up, in the backlight source manufacturing method provided in this embodiment of the present disclosure, the two conductive structures are respectively formed on a side of the light emitting units that is proximal to the substrate and a side of the light emitting units that is distal from the substrate, so that both the conductive structures on the two sides of the light emitting units have relatively large disposing space, thereby facilitating an increase in a width of the electrode cable in the conductive structure. In this way, there is no need to form an excessively thick electrode cable by a plurality of patterning processes. Compared with a solution in which a relatively thick anode cable and a relatively thick cathode cable are formed by a plurality of patterning processes, based on the method provided in this application, a quantity of patterning processes is reduced, and manufacturing costs are reduced.

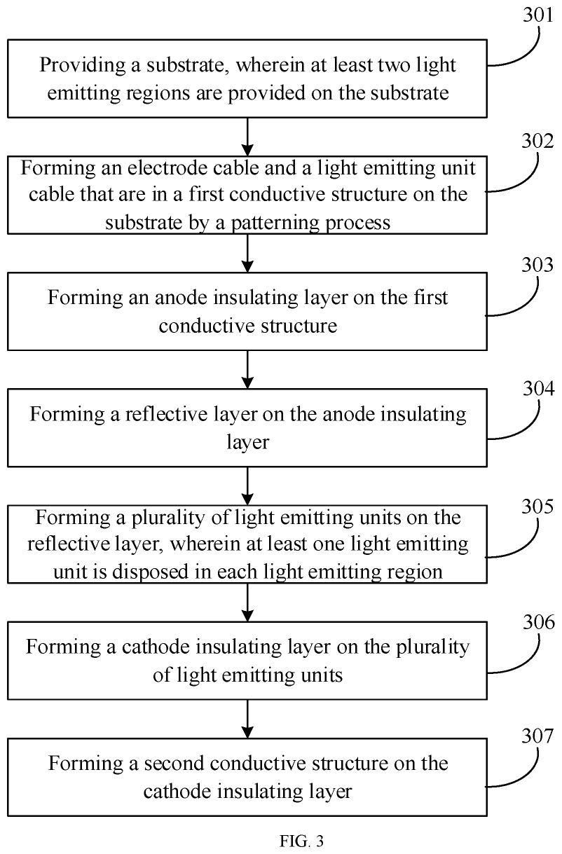

FIG. 3 is a flowchart of another backlight source manufacturing method according to an embodiment of the present disclosure. The method includes the following steps.

In step 301, a substrate is provided, wherein at least two light emitting regions are provided on the substrate.

The substrate may be a transparent substrate, and a material of the substrate may include glass.

The at least two light emitting regions are provided based on a display contrast requirement of a display apparatus. A larger quantity of light emitting regions leads to higher fineness of controlling a backlight source, a higher display contrast of the corresponding display apparatus, and a better display effect.

In step 302, an electrode cable and a light emitting unit cable that are in the first conductive structure are formed on the substrate by a patterning process.

At least two light emitting units are disposed in each light emitting region, the light emitting unit cable is used to connect the at least two light emitting units in any light emitting region, at least a part of the electrode cable in the first conductive structure is out of the light emitting regions, an electrode cable included in one of the first conductive structure and the second conductive structure is an anode cable, and an electrode cable included in the other conductive structure is a cathode cable. In this embodiment of this application, description is provided by using an example in which the electrode cable included in the first conductive structure is an anode cable and an electrode cable included in the second conductive structure is a cathode cable. However, this is not limited. The first conductive structure may include a plurality of anode cables, which are configured to control a plurality of light emitting units.

The electrode cable and the light emitting unit cable that are in the first conductive structure may be formed by one patterning process, to reduce manufacturing steps, and reduce an entire thickness of the backlight source.

In this embodiment of this application, the used patterning process may include steps such as photoresist forming, exposure, development, etching, and photoresist stripping.

Each light emitting region needs to be driven and controlled by using a relatively large driving current, but a relatively small current is required between light emitting units in each light emitting region.

Therefore, in an optional manner, either of a width of the electrode cable in the first conductive structure and a width of the electrode cable in the second conductive structure is greater than a width of the light emitting unit cable. In addition, the electrode cable has a same thickness as the light emitting unit cable.

A serial connection relationship, a parallel connection relationship, or both a serial connection relationship and a parallel connection relationship exist between light emitting units in each light emitting region.

Therefore, in an optional manner, the light emitting unit cable includes a serial connection cable, a parallel connection cable, or both a serial connection cable and a parallel connection cable.

In an optional manner, a material of the electrode cable and the light emitting unit cable that are in the first conductive structure includes copper. Copper has relatively high conductivity. In this way, conductivity of the first conductive structure and the light emitting unit cable can be enhanced, and resistance can be reduced.

In addition, the material of the first conductive structure and the light emitting unit cable may further include aluminum. This is not limited in this embodiment of this application.

In an optional manner, the first conductive structure includes a molybdenum-niobium alloy layer, a copper layer, and another molybdenum-niobium alloy layer which are sequentially stacked. The molybdenum-niobium alloy layer may enhance adhesive force between the first conductive structure and the substrate, and prevent the first conductive structure from being oxidized.

That the first conductive structure is formed on the substrate in step 302 includes:

forming, on the substrate by the patterning process, the first conductive structure constituted by a molybdenum-niobium alloy layer, a copper layer, and another molybdenum-niobium alloy layer which are sequentially stacked.

When a first cable is an anode cable, an anode insulating layer may be formed on the first conductive structure.

In step 303, the anode insulating layer is formed on the first conductive structure.

The anode insulating layer is formed on the first conductive structure. The anode insulating layer may include a silicon nitride layer (or a silicon dioxide layer) and a resin layer which are stacked, and the resin layer may also have a planarization effect.

In step 304, a reflective layer is formed on the anode insulating layer.

The reflective layer is configured to reflect light emitted by the light emitting unit, to improve light exitance. The reflective layer may include two transparent indium tin oxide layers and a metallic silver layer sandwiched therebetween. Reflectivity of metallic silver is relatively high, which can improve light exitance. The indium tin oxide layer can protect the metallic silver layer.

In step 305, a plurality of light emitting units are formed on the reflective layer, wherein at least one light emitting unit is disposed in each light emitting region.

The light emitting unit may be a mini LED, namely a mini light emitting diode. The mini LED is a transition product from an ordinary LED to a micro LED, and has a much smaller size than the ordinary LED. Generally, the size is approximately 100 microns. When the mini LED is used as a backlight source of an LCD screen, not only light emitting regions can be made more delicate, to reach a high dynamic range, and show a high contrast effect, but also an optical distance can be shortened to reduce a thickness of an entire machine, thereby meeting a thinning requirement.

The light emitting region may be rectangular. Four light emitting units may be disposed in each light emitting region, and are respectively disposed in four corners of the rectangular light emitting region.

Before the light emitting units are formed in step 305, a hole may be first formed at a light emitting layer and the anode insulating layer, so that an anode of the light emitting unit is connected to the anode cable.

In an exemplary embodiment, the light emitting unit may include a wafer, and an anode and a cathode on two sides of the wafer in a direction perpendicular to the substrate. Before the reflective layer is formed in step 304, the hole may be first formed at the anode insulating layer by the patterning process, and the light emitting unit cable is exposed from the hole. Then after the reflective layer is formed in step 304, an opening is formed at the reflective layer by the patterning process, so that the hole at the anode insulating layer is exposed from the opening. Then in step 305, a conductive silver adhesive may be formed in the hole at the anode insulating layer, and the anode of the light emitting unit is electrically connected to the conductive silver adhesive, so that the anode of the light emitting unit is electrically connected to the light emitting unit cable.

In step 306, a cathode insulating layer is formed on the plurality of light emitting units.

A material of the cathode insulating layer may include silicon nitride, silicon dioxide, or resin.

In step 307, the second conductive structure is formed on the cathode insulating layer.

The second conductive structure may overlap the light emitting region, and the electrode cable included in the second conductive structure may be a cathode cable. The second conductive structure may include a plurality of cathode cables, and the plurality of cathode cables cooperate with the plurality of anode cables in the first conductive structure to control the plurality of light emitting units.

A material of the second conductive structure may include a transparent conductive indium tin oxide layer, to avoid blocking light emitted by the light emitting unit while conductivity is ensured.

In an optional manner, after the second conductive structure is formed, a protective layer may be further formed on the second conductive structure, and a material of the protective layer may include silicon nitride.

It may be understood that the electrode cable included in the first conductive structure and the electrode cable included in the second conductive structure are configured to control luminance of the light emitting unit in the light emitting region. Therefore, both the first conductive structure and the second conductive structure are electrically connected to the light emitting unit in the light emitting region. Specifically, an electrical connection may be established between different layers through perforating.

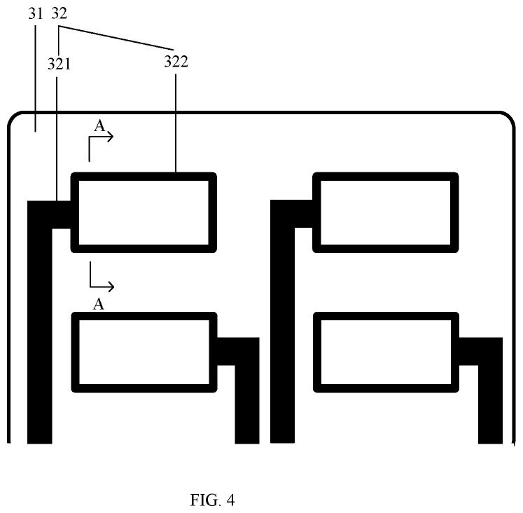

FIG. 4 is a schematic diagram of a top view structure of the backlight source after step 302 ends. A first conductive structure 32 including an anode cable 321 and a light emitting unit cable 322 is formed on a buffer layer 31, the anode cable 321 is electrically connected to the light emitting unit cable 322, and a width of at least one anode cable 321 is greater than a width of the light emitting unit cable 322.

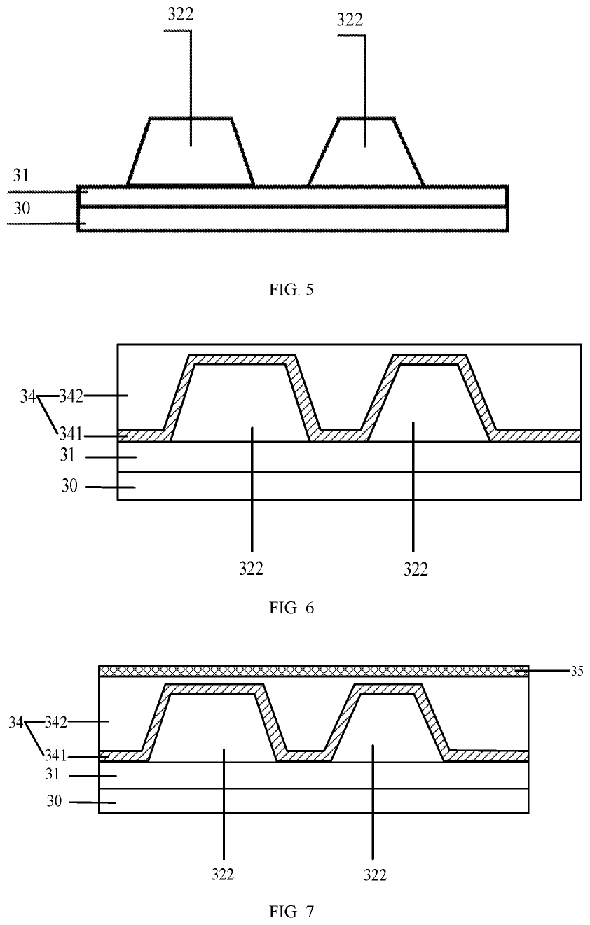

FIG. 5 is a schematic cross-sectional view at a position A-A in FIG. 4. The buffer layer 31 and the light emitting unit cable 322 on the buffer layer 31 are disposed on a substrate 30.

FIG. 6 is a schematic cross-sectional view of each structure on the substrate when step 303 ends. An anode insulating layer 34 is formed on the light emitting unit cable 322. Optionally, the anode insulating layer 34 may include a silicon nitride layer 341 (or a silicon dioxide layer) and a resin layer 342 that are sequentially disposed in a direction distal from the substrate 30.

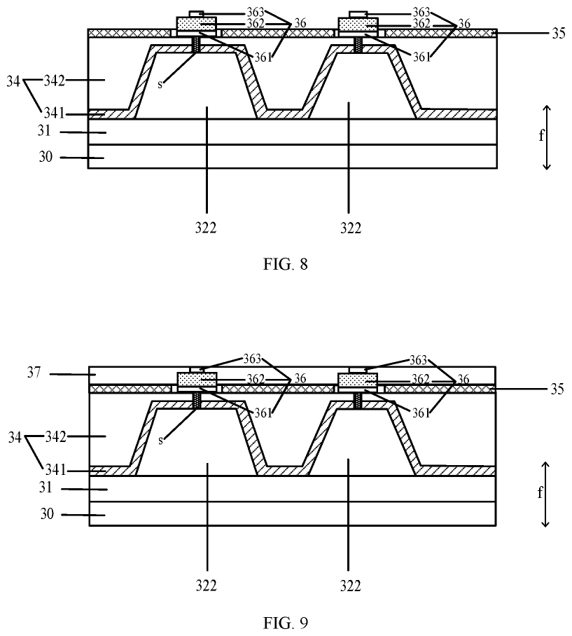

FIG. 7 is a schematic cross-sectional view of each structure on the substrate when step 304 ends. A reflective layer 35 is formed on the anode insulating layer 34.

FIG. 8 is a schematic cross-sectional view of each structure on the substrate when step 305 ends. A light emitting unit 36 is formed at an opening of the reflective layer 35. Light emitted by the light emitting unit 36 can be reflected by the reflective layer 35 to a light emitting side (that is, an upper side shown in FIG. 8) of the backlight source. In this way, light emitting efficiency of the light emitting unit 36 can be increased.

In an exemplary embodiment, the light emitting unit 36 may include a wafer 362, and an anode 361 and a cathode 363 that are on two sides of the wafer 362 in a direction f perpendicular to the substrate 30. The reflective layer 35 may have an opening (the opening is not marked in FIG. 8, and may be formed before step 305, for example, the opening may be formed on the reflective layer 35 by the patterning process after the reflective layer 35 is formed), to avoid the anode 361. The anode 361 may be electrically connected to the light emitting unit cable 322 (referring to FIG. 4, the light emitting unit cable 322 may be electrically connected to the anode cable 321). Optionally, the anode insulating layer 34 has a hole (the hole may be formed before step 305 or after step 304). A conductive silver adhesive s is disposed in the hole, and the anode 361 may be electrically connected to the light emitting unit cable 322 by using the conductive silver adhesive s.

FIG. 9 is a schematic structural diagram of the backlight source when step 306 ends. A cathode insulating layer 37 is formed on the light emitting unit 36. The cathode insulating layer 37 may prevent a short circuit between a subsequently formed electrode cable and an underlying structure. A hole may be formed at the cathode insulating layer 37, and the cathode 363 of the light emitting unit may be exposed from the hole, so that the cathode 363 is electrically connected to a subsequently formed cathode cable.

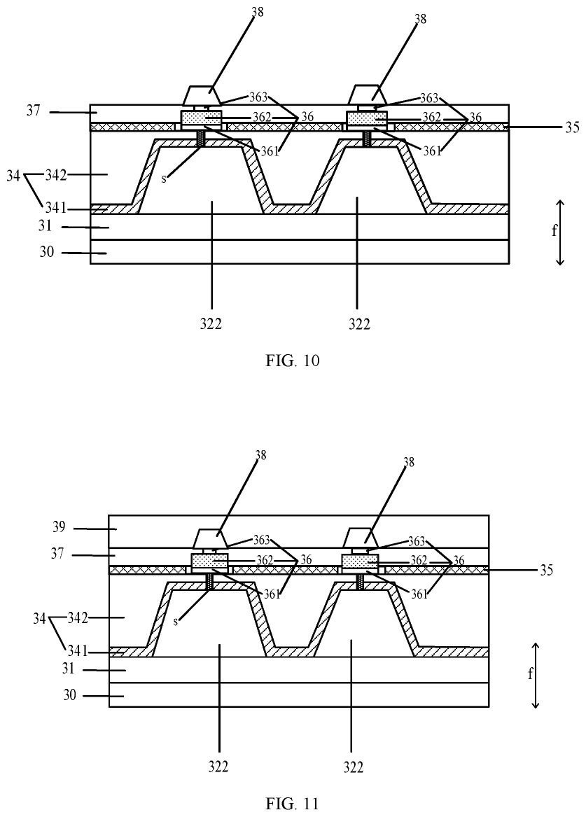

FIG. 10 is a schematic structural diagram of the backlight source when step 307 ends. A second conductive structure 38 is formed on the cathode insulating layer 37. The second conductive structure 38 may include a cathode cable, and the cathode cable in the second conductive structure 38 is electrically connected to the cathode 363 of the light emitting unit. The second conductive structure 38 may be constituted by a transparent conductive material (such as indium tin oxide), to avoid blocking light emitted by the light emitting unit.

FIG. 11 is a schematic structural diagram of a backlight source after a protective layer is formed. A protective layer 39 is formed on the second conductive structure 38. The protective layer 39 may protect underlying structures, such as the second conductive structure 38 and the light emitting unit 36.

To sum up, in the technical solution provided in this embodiment of the present disclosure, the two conductive structures are respectively formed on a side of the light emitting units that is proximal to the substrate and a side of the light emitting units that is distal from the substrate, so that both the conductive structures on the two sides of the light emitting units have relatively large disposing space, thereby facilitating an increase in a width of the electrode cable in the conductive structure. In this way, there is no need to form an excessively thick electrode cable by a plurality of patterning processes. Compared with a solution in which a relatively thick anode cable and a relatively thick cathode cable are formed by a plurality of patterning processes, based on the method provided in this application, a quantity of patterning processes is reduced, and manufacturing costs are reduced.

In the backlight source manufacturing method shown in FIG. 3, the second conductive structure includes the plurality of cathode cables. However, in an optional manner, the electrode cable included in the second conductive structure may be a conductive layer, the conductive layer may be connected to cathodes of a plurality of conductive structures, and the cathodes cooperate with the plurality of anode cables in the first conductive structure to control the plurality of light emitting units. In addition, the conductive layer may also function as the protective layer in the backlight source, to reduce a quantity of patterning processes. A specific embodiment is described as follows.

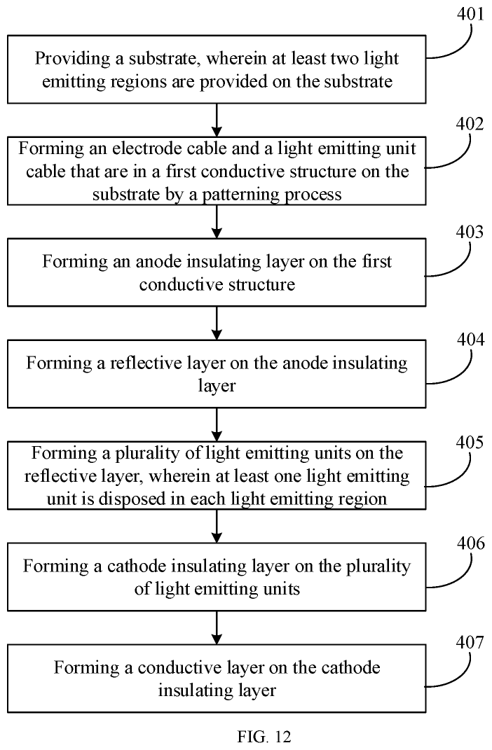

FIG. 12 is a flowchart of another backlight source manufacturing method according an embodiment of the present disclosure. In this embodiment of this application, a used patterning process may include steps such as photoresist forming, exposure, development, etching, and photoresist stripping.

The method includes the following steps.

In step 401, a substrate is provided, wherein at least two light emitting regions are provided on the substrate.

The substrate may be a transparent substrate, and a material of the substrate may include glass.

The at least two light emitting regions are provided based on a display contrast requirement of a display apparatus. A larger quantity of light emitting regions leads to higher fineness of controlling a backlight source, a higher display contrast of the corresponding display apparatus, and a better display effect.

In step 402, an electrode cable and a light emitting unit cable that are in a first conductive structure are formed on the substrate by a patterning process.

At least two light emitting units are disposed in each light emitting region, the light emitting unit cable is configured to connect the at least two light emitting units in any light emitting region, at least a part of the electrode cable in the first conductive structure may be out of the light emitting regions, and a first cable may be an anode cable.

The electrode cable and the light emitting unit cable that are in the first conductive structure may be formed by one patterning process, to reduce manufacturing steps, and reduce an entire thickness of the backlight source.

In an optional manner, a buffer layer may be further disposed between the substrate and the first conductive structure, and a material of the buffer layer may include silicon nitride.

In an optional manner, the electrode cable and the light emitting unit cable that are in the first conductive structure may be manufactured at two layers and are formed by two patterning processes. In addition, after the electrode cable in the first conductive structure is formed, a unit cable insulating layer may be disposed on the electrode cable, so that the first conductive structure and the light emitting unit cable do not affect each other due to existence of the unit cable insulating layer even if there are a relatively large quantity of light emitting regions, and the entire backlight source can be made more compact.

Each light emitting region needs to be driven and controlled by using a relatively large driving current, but a relatively small current is required between light emitting units in each light emitting region.

Therefore, in an optional manner, a width of the electrode cable is greater than a width of the light emitting unit cable. In addition, the electrode cable has a same thickness as the light emitting unit cable.

That the first conductive structure is formed on the substrate in step 402 includes:

forming, on the substrate by the patterning process, the first conductive structure constituted by a molybdenum-niobium alloy, copper, and another molybdenum-niobium alloy which are sequentially stacked.

When the first cable is the anode cable, an anode insulating layer is formed on the first cable.

In step 403, the anode insulating layer is formed on the first conductive structure.

The anode insulating layer is formed on the first conductive structure. The anode insulating layer may include a silicon nitride layer (or a silicon dioxide layer) and a resin layer which are stacked, and the resin layer may also have a planarization effect.

In step 404, a reflective layer is formed on the anode insulating layer.

The reflective layer is configured to reflect light emitted by the light emitting unit, to improve light exitance.

The reflective layer may include two transparent indium tin oxide layers and a metallic silver layer sandwiched therebetween. Reflectivity of metallic silver is relatively high, which can improve the light exitance. The indium tin oxide layer can protect the metallic silver layer.

In step 405, a plurality of light emitting units are formed on the reflective layer, wherein at least one light emitting unit is disposed in each light emitting region.

The light emitting unit may be a mini LED, and the light emitting region may be rectangular. Four light emitting units may be disposed in each light emitting region, and are respectively disposed in four corners of the rectangular light emitting region. This step can be further referred to step 305 in the foregoing embodiment, and is not described herein again.

In step 406, a cathode insulating layer is formed on the plurality of light emitting units.

A material of the cathode insulating layer may include silicon nitride, silicon dioxide, or resin.

In step 407, a conductive layer is formed on the cathode insulating layer.

Steps 401 to 406 in this embodiment are similar to steps 301 to 306 in the previous embodiment. Therefore, the forming process before step 407 can be referred to FIG. 4 to FIG. 10 in the previous embodiment.

A greatest difference between this embodiment and the previous embodiment is as follows: step 407 in this embodiment is used to replace step 307 and the protective layer forming step in the previous embodiment, to reduce a quantity of patterning processes.

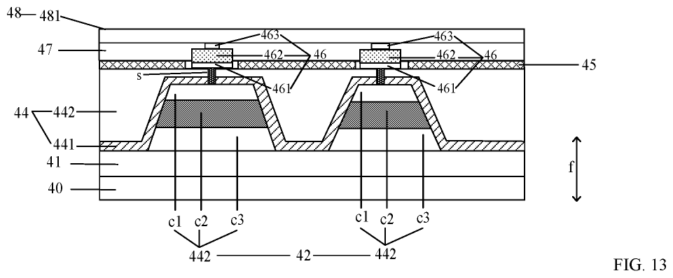

FIG. 13 is a schematic structural diagram of the backlight source when step 407 ends. A conductive layer 481 included in a second conductive structure 48 is formed on a cathode insulating layer 47. A substrate 40, a buffer layer 41, a light emitting unit cable 422, an anode insulating layer 44, a reflective layer 45, and a light emitting unit 46 are further included in FIG. 13. The light emitting unit 46 includes a wafer 462, and an anode 461 and a cathode 463 that are on two sides of the wafer 462 in a direction perpendicular to the substrate 40. The conductive layer 481 is electrically connected to the cathode 463. The anode insulating layer 44 may include a silicon nitride layer (or a silicon dioxide layer) and a resin layer which are stacked.

A first conductive structure 42 includes a first molybdenum-niobium alloy layer c1, a copper layer c2, and a second molybdenum-niobium alloy layer c3 which are stacked.

In an optional manner, a material of the conductive layer includes indium tin oxide or a magnesium-copper alloy.

All cathodes of light emitting units in the backlight source may be connected to the conductive layer, and both the conductive layer and an electrode cable in the first conductive structure may load a voltage for the light emitting units in the backlight source, to drive the light emitting units to emit light. In such a structure, the conductive layer may be considered as a common cathode of the plurality of light emitting units.

The conductive layer not only can cooperate with the electrode cable in the first conductive structure to drive the light emitting unit, but also can function as a protective layer in a traditional backlight source, thereby eliminating steps of individually manufacturing the protective layer, and reducing a quantity of patterning processes.

Both the indium tin oxide and the magnesium-copper alloy have relatively desirable conductivity, the indium tin oxide has high transparency, and the magnesium-copper alloy has relatively desirable transparency with a relatively small thickness, to increase light transmittance of the backlight source while conductivity of the conductive layer is ensured.

It may be understood that the electrode cable in the first conductive structure and the conductive layer in the second conductive structure are configured to control luminance of the light emitting unit in the light emitting region. Therefore, both the electrode cable in the first conductive structure and the conductive layer in the second conductive structure are electrically connected to the light emitting unit in the light emitting region. Specifically, an electrical connection may be established between different layers through perforating.

To sum up, in the backlight source manufacturing method provided in this embodiment of the present disclosure, the two conductive structures are respectively formed on a side of the light emitting units that is proximal to the substrate and a side of the light emitting units that is distal from the substrate, so that both the conductive structures on the two sides of the light emitting units have relatively large disposing space, thereby facilitating an increase in a width of the electrode cable in the conductive structure. In this way, there is no need to form an excessively thick electrode cable by a plurality of patterning processes. Compared with a solution in which a relatively thick anode cable and a relatively thick cathode cable are formed by a plurality of patterning processes, based on the method provided in this application, a quantity of patterning processes is reduced, and manufacturing costs are reduced. In addition, the electrode cable and the light emitting unit cable that are in the first conductive structure are formed at a same layer by one patterning process, to reduce an entire thickness of the backlight source while manufacturing steps are reduced. In addition, the conductive layer is used as the cathode in the backlight source, so that the conductive layer not only can play a role of the cathode, but also can function as a protective layer in a traditional backlight source, thereby eliminating steps of individually manufacturing the protective layer, and reducing a quantity of patterning processes.

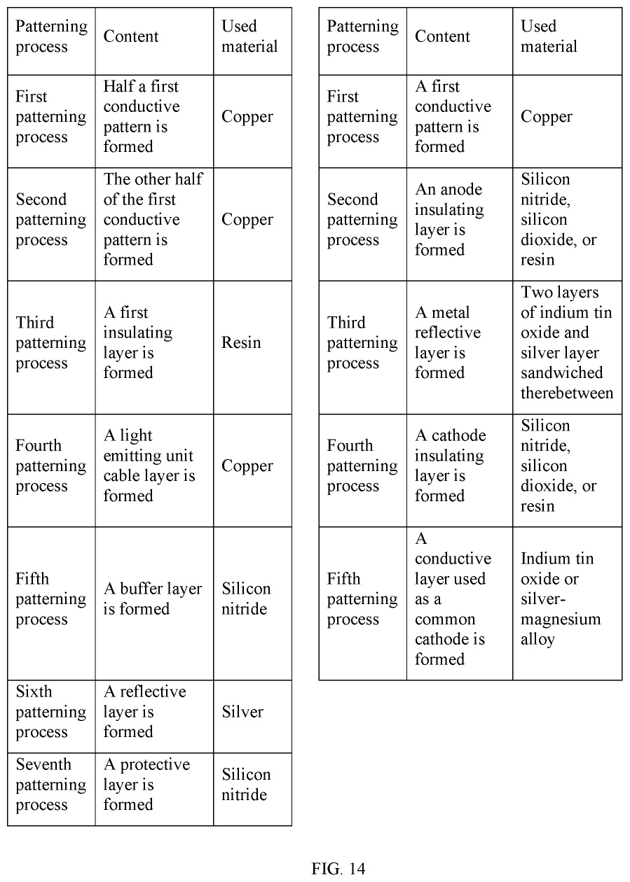

As shown in the left part of FIG. 14, if a backlight source manufacturing method in the related art is used, seven patterning processes may be performed: When a first patterning process is performed, half a first conductive pattern is formed, and a material of the first conductive pattern includes metal Cu. When a second patterning process is performed, the other half of the first conductive pattern is formed. When a third patterning process is performed, a first insulating layer is formed, and a material of the first insulating layer may include resin. When a fourth patterning process is performed, a light emitting unit cable layer is formed, and a material of the light emitting unit cable layer includes metal Cu. When a fifth patterning process is performed, a buffer layer is formed, and a material of the buffer layer includes silicon nitride. When a sixth patterning process is performed, a reflective layer is formed. When a seventh patterning process is performed, a protective layer is formed. In the related art, because first conductive patterns are all disposed inside light emitting regions, the first conductive patterns can only be set to be relatively narrow and thick, and metal needs to be shaped twice by performing two steps. In addition, the protective layer needs to be independently disposed. There are relatively many steps in the patterning process, and manufacturing costs are relatively high.

As shown in the right part of FIG. 14, when the backlight source manufacturing method provided in this embodiment of the present disclosure is used, five patterning processes may be performed: When a first patterning process is performed, a first conductive structure is formed, and a material of the first conductive structure includes metal Cu. When a second patterning process is performed, an anode insulating layer is formed, and a material of the anode insulating layer includes silicon nitride, silicon dioxide, or resin. When a third patterning process is performed, a metal reflective layer is formed, and a material of the metal reflective layer is two layers of indium tin oxide and a silver layer sandwiched therebetween. When a fourth patterning process is performed after a light emitting unit is disposed, a cathode insulating layer is formed, and a material of the cathode insulating layer includes silicon nitride, silicon dioxide, or resin. When a fifth patterning process is performed, a conductive layer considered as a common cathode is formed, and a material of the conductive layer includes indium tin oxide or a silver-magnesium alloy. It can be seen that, when the backlight source manufacturing method provided in this embodiment of the present disclosure is used, the five patterning processes are performed, thereby greatly simplifying a backlight source manufacturing procedure, and reducing manufacturing costs.

FIG. 11 is a schematic structural diagram of a backlight source according to an embodiment of the present disclosure. The backlight source is manufactured by using the backlight source manufacturing method shown in FIG. 3, and includes:

a substrate 30, and a first conductive structure 32, a plurality of light emitting units 36, and a second conductive structure 38 which are stacked on the substrate 30; wherein the first conductive structure 32 and the second conductive structure 38 are respectively on two sides of the plurality of light emitting units 36 in a direction f perpendicular to the substrate 30, and the first conductive structure 32 and the second conductive structure 38 are configured to load a voltage for the plurality of light emitting units 36.

To sum up, for the backlight source provided in this embodiment of the present disclosure, the two conductive structures are respectively disposed on a side of the light emitting units that is proximal to the substrate and a side of the light emitting units that is distal from the substrate, so that both the conductive structures on the two sides of the light emitting units have relatively large disposing space, thereby facilitating an increase in a width of the electrode cable in the conductive structure. In this way, there is no need to form an excessively thick electrode cable by a plurality of patterning processes. Compared with a solution in which a relatively thick anode cable and a relatively thick cathode cable are formed by a plurality of patterning processes, based on the method provided in this application, a quantity of patterning processes is reduced, and manufacturing costs are reduced.

Each of the first conductive structure 32 and the second conductive structure 38 may include an electrode cable. The electrode cable in the first conductive structure 32 and the electrode cable in the second conductive structure 38 may load a voltage for the light emitting units 36, so that the light emitting units 36 emit light.

In an optional manner, the backlight source includes a light emitting unit cable 322 that is formed by a same pattering process as the electrode cable in the first conductive structure 32, there may be a plurality of light emitting unit cables 322, at least two light emitting units 36 are disposed in each light emitting region, and the light emitting unit cable 322 is used to connect the at least two light emitting units 36 in any light emitting region.

To sum up, in the backlight source provided in this embodiment of the present disclosure, the first conductive structure and the light emitting unit cable are formed at a same layer by the same patterning process, thereby reducing an entire thickness of the backlight source while mask manufacturing steps are reduced.

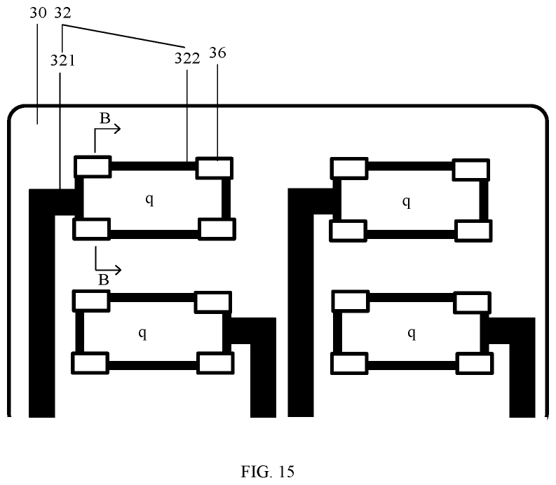

FIG. 15 is a top view of the backlight source shown in FIG. 11 (for ease of indication, the second conductive structure is not shown in FIG. 15), and FIG. 11 is a schematic cross-sectional view at a position B-B in FIG. 15. At least two light emitting regions q are provided on the substrate 30, the first conductive structure 32 includes at least two light emitting unit cables 322 that are in a one-to-one correspondence with the at least two light emitting regions q, and each light emitting unit cable 322 is configured to connect light emitting units 36 in a corresponding light emitting region q.

At least a part of at least one of the first conductive structure 32 and the second conductive structure is out of the light emitting regions q.

At least one of the first conductive structure 32 and the second conductive structure includes a plurality of electrode cables, and a width of the electrode cable is greater than a width of the light emitting unit cable. In FIG. 15, a width of one or more of electrode cables 321 in the first conductive structure 32 and electrode cables in the second conductive structure may be greater than the width of the light emitting unit cable 322. A width of a cable may be a size at a position of the cable perpendicular to an extension direction of the cable.

A serial connection relationship, a parallel connection relationship, or both a serial connection relationship and a parallel connection relationship exist between light emitting units in each light emitting region.

Therefore, in an optional manner, the light emitting unit cable 322 includes a serial connection cable, a parallel connection cable, or both a serial connection cable and a parallel connection cable.

The top view 15 shows four light emitting regions q, and four light emitting units 36 are disposed in each light emitting region q. The four light emitting units 36 are respectively disposed in four corners of the rectangular light emitting region q, and the light emitting unit cable 36 serially connects the four light emitting units.

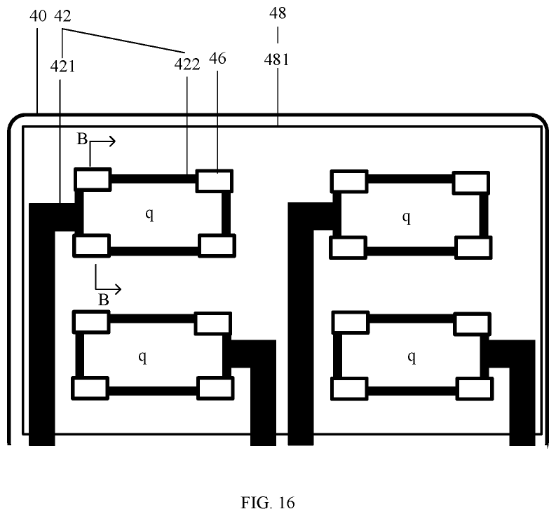

FIG. 16 is a schematic diagram of a top view structure of a backlight source according to an embodiment of the present disclosure. The backlight source is manufactured by using the backlight source manufacturing method shown in FIG. 12, and includes:

a substrate 40, wherein at least two light emitting regions q are provided on the substrate 40.

A first conductive structure 42 is disposed on the substrate 40, and an electrode cable 421 in the first conductive structure 42 is out of the at least two light emitting regions q.

A plurality of light emitting units 46 are disposed on the first conductive structure 42, and at least one light emitting unit 46 is disposed in each light emitting region q.

A second conductive structure 48 is disposed on the plurality of light emitting units 46, the second conductive structure 48 overlaps the at least two light emitting regions q, the second conductive structure 48 includes a conductive layer 481 used as a common cathode, and the electrode cable 421 in the first conductive structure 42 is an anode cable.

The first conductive structure 42 further includes a light emitting unit cable 422 formed by using a same patterning process as the electrode cable 421, at least two light emitting units 46 are disposed in each light emitting region q, and the light emitting unit cable 422 is used to connect the at least two light emitting units 46 in any light emitting region q.

The schematic cross-sectional view at the position B-B in FIG. 16 may be referred to FIG. 13. As shown in FIG. 13, the backlight source includes the substrate 40, and the first conductive structure 42, the plurality of light emitting units 46, and the second conductive structure 48 which are stacked on the substrate 40.

The first conductive structure 42 includes the first molybdenum-niobium alloy layer c1, the copper layer c2, and the second molybdenum-niobium alloy layer c3 which are stacked, in other words, both the anode cable and the light emitting unit cable 422 that are in the first conductive structure 42 may be constituted by the three layers. The second conductive structure 48 includes the conductive layer 481. The backlight source further includes the anode insulating layer 44, the metal reflective layer 45, and the cathode insulating layer 47.

The buffer layer 41 may be further disposed between the substrate 40 and the first conductive structure 42, and a material of the buffer layer 41 includes silicon nitride.

To sum up, for the backlight source provided in this embodiment of the present disclosure, the two conductive structures are respectively disposed on a side of the light emitting units that is proximal to the substrate and a side of the light emitting units that is distal from the substrate, so that both the conductive structures on the two sides of the light emitting units have relatively large disposing space, thereby facilitating an increase in a width of the electrode cable in the conductive structure. In this way, there is no need to form an excessively thick electrode cable by a plurality of patterning processes. Compared with a solution in which a relatively thick anode cable and a relatively thick cathode cable are formed by a plurality of patterning processes, based on the method provided in this application, a quantity of patterning processes is reduced, and manufacturing costs are reduced. In addition, the electrode cable and the light emitting unit cable that are in the first conductive structure are formed at a same layer by one patterning process, to reduce an entire thickness of the backlight source while manufacturing steps are reduced. In addition, the conductive layer is used as the cathode in the backlight source, so that the conductive layer not only can play a role of the cathode, but also can function as a protective layer in a traditional backlight source, thereby eliminating steps of individually manufacturing the protective layer, and reducing a quantity of patterning processes.

In addition, an embodiment of the present disclosure provides a display apparatus. The display apparatus includes a display panel and the backlight source provided in the foregoing embodiment.

The term “and/or” in the present disclosure merely describes the association relationship between the associated objects and indicates that there may be three relationships; for example, A and/or B may indicate three cases where only A exists, A and B exist at the same time, and only B exists. The character “/” in the present disclosure generally indicates that the relationship between the former and later associated objects is “OR”.

The foregoing descriptions are merely optional embodiments of the present disclosure, and are not intended to limit the present disclosure. Within the spirit and principles of the disclosure, any modifications, equivalent substitutions, improvements, etc., are within the protection scope of the present disclosure.

According to a first aspect, a backlight source manufacturing method is provided, and the method includes:

providing a substrate, wherein at least two light emitting regions are provided on the substrate;

forming a first conductive pattern on the substrate, wherein the first conductive pattern is out of the at least two light emitting regions, and includes a plurality of first cables;

forming a plurality of light emitting units on the substrate on which the first conductive pattern is formed, wherein at least one light emitting unit is disposed in each light emitting region; and

forming a second conductive pattern on the substrate on which the plurality of light emitting units are formed, wherein the second conductive pattern overlaps the at least two light emitting regions and includes a plurality of second cables, one of the first cable and the second cable is a cathode cable, and the other cable is an anode cable.

Optionally, the second cable is a cathode cable, and forming a second conductive pattern on the substrate on which the plurality of light emitting units are formed includes:

forming a common cathode layer on the substrate on which the plurality of light emitting units are formed.

Optionally, at least two light emitting units are disposed in each light emitting region, and forming a first conductive pattern on the substrate includes:

forming the first conductive pattern and a light emitting unit cable pattern on the substrate by a patterning process, wherein the light emitting unit cable pattern includes a plurality of light emitting unit cables, and the light emitting unit cable is used to connect the at least two light emitting units in any light emitting region.

Optionally, each of a width of a cathode cable and a width of an anode cable is greater than a width of the light emitting unit cable.

Optionally, the light emitting unit cable includes a serial connection cable and/or a parallel connection cable.

Optionally, a material of the first conductive pattern and the light emitting unit cable includes copper.

Optionally, after the plurality of light emitting units are formed on the substrate on which the first conductive pattern is formed, the method further includes:

forming a cathode insulating layer on the substrate on which the plurality of light emitting units are formed.

Optionally, forming a second conductive pattern on the substrate on which the plurality of light emitting units are formed includes:

forming the second conductive pattern on the substrate on which the cathode insulating layer is formed

Optionally, a material of the common cathode layer includes indium tin oxide or a magnesium-copper alloy.

Optionally, the first conductive pattern includes a lamination film layer constituted by a molybdenum-niobium alloy, copper, and another molybdenum-niobium alloy which are sequentially stacked, and

forming a first conductive pattern on the substrate includes:

forming, on the substrate by the patterning process, the first conductive pattern constituted by molybdenum-niobium alloy, copper and another molybdenum-niobium alloy which are sequentially stacked.

Optionally, after forming a first conductive pattern on the substrate, the method further includes:

forming an anode insulating layer on the substrate on which the first conductive pattern is formed; and

forming a reflective layer on the substrate on which the anode insulating layer is formed.

Forming a plurality of light emitting units on the substrate on which the first conductive pattern is formed includes:

forming the plurality of light emitting units on the substrate on which the reflective layer is formed.

According to a second aspect, a backlight source is provided, and the backlight source includes:

a substrate, wherein at least two light emitting regions are provided on the substrate.

A first conductive pattern is disposed on the substrate. The first conductive pattern is out of the at least two light emitting regions, and includes a plurality of first cables.

A plurality of light emitting units are disposed on the substrate on which the first conductive pattern is disposed, and at least one light emitting unit is disposed in each light emitting region.

A second conductive pattern is disposed on the substrate on which the plurality of light emitting units are disposed, the second conductive pattern overlaps the at least two light emitting regions and includes a plurality of second cables, one of the first cable and the second cable is a cathode cable, and the other cable is an anode cable.

Optionally, the second cable is a cathode cable, and the second conductive pattern is a common cathode layer.

According to a third aspect, a display apparatus is provided. The display apparatus includes a display panel and the backlight source provided in the first or second aspect.

The technical solutions provided in the present disclosure at least have the following beneficial effects:

For the backlight source manufacturing method, the backlight source, and the display apparatus that are provided in the present disclosure, the backlight source manufacturing method includes: providing the substrate, wherein the at least two light emitting regions are provided on the substrate; forming the first conductive pattern on the substrate, wherein the first conductive pattern is out of the at least two light emitting regions, and include the plurality of first cables; forming the plurality of light emitting units on the substrate on which the first conductive pattern is formed, wherein at least one light emitting unit is disposed in each light emitting region; and forming the second conductive pattern on the substrate on which the plurality of light emitting units are formed, wherein the second conductive pattern overlaps the at least two light emitting regions, and includes a plurality of second cables, one of the first cable and the second cable is a cathode cable, and the other cable is an anode cable. The anode cable or the cathode cable is removed from the light emitting region, is disposed out of the light emitting region, and does not overlap the light emitting region. Therefore, compared with a disposing manner in which both the anode cable and the cathode cable overlap the light emitting region in the related art, an area on the substrate except the light emitting region can be fully used, so that each cable can be set to be wider and thinner and formed without a plurality of patterning processes, thereby reducing a quantity of patterning processes, and reducing manufacturing costs.

What is claimed is:

1. A backlight source comprising:
a substrate, and a first conductive structure, a plurality of light emitting units, and a second conductive structure which are stacked on the substrate, wherein the first conductive structure and the second conductive structure are respectively on two sides of the plurality of light emitting units in a direction perpendicular to the substrate, and the first conductive structure and the second conductive structure are configured to load a voltage for the plurality of light emitting units.

2. The backlight source according to claim 1, wherein one of the first conductive structure and the second conductive structure is a conductive layer.

3. The backlight source according to claim 1, wherein at least two light emitting regions are provided on the substrate, and at least two light emitting units are disposed in each light emitting region; and
the first conductive structure comprises at least two light emitting unit cables which are in a one-to-one correspondence with the at least two light emitting regions, and each light emitting unit cable is configured to connect light emitting units in a corresponding light emitting region.

4. The backlight source according to claim 3, wherein at least a part of at least one of the first conductive structure and the second conductive structure is out of the light emitting regions.

5. The backlight source according to claim 3, wherein at least one of the first conductive structure and the second conductive structure comprises a plurality of electrode cables, and a width of the electrode cable is greater than a width of the light emitting unit cable.

6. The backlight source according to claim 1, wherein the backlight source comprises an insulating layer which is between the plurality of light emitting units and the second conductive structure.

7. The backlight source according to claim 2, wherein the second conductive structure is a cathode conductive layer.

8. The backlight source according to claim 2, wherein a material of the conductive layer comprises indium tin oxide.

9. The backlight source according to claim 2, wherein a material of the conductive layer comprises a magnesium-copper alloy.

10. The backlight source according to claim 3, wherein a material of the first conductive structure comprises copper.

11. The backlight source according to claim 3, wherein the first conductive structure comprises a molybdenum-niobium alloy layer, a copper layer, and another molybdenum-niobium alloy layer which are stacked.

12. The backlight source according to claim 1, wherein the second conductive structure is a cathode conductive layer;
at least two light emitting regions are provided on the substrate, and at least two light emitting units are disposed in each light emitting region;
the first conductive structure comprises at least two light emitting unit cables which are in a one-to-one correspondence with the at least two light emitting regions, and each light emitting unit cable is configured to connect light emitting units in a corresponding light emitting region;
the first conductive structure comprises a plurality of electrode cables, and a width of the electrode cable is greater than a width of the light emitting unit cable; and
at least a part of the electrode cable in the first conductive structure is out of the light emitting regions.

13. A backlight source manufacturing method, comprising:
providing a substrate; and
sequentially forming, on the substrate, a first conductive structure, a plurality of light emitting units, and a second conductive structure which are stacked, wherein the first conductive structure and the second conductive structure are respectively on two sides of the plurality of light emitting units in a direction perpendicular to the substrate, and the first conductive structure and the second conductive structure are configured to load a voltage for the plurality of light emitting units.

14. The method according to claim 13, wherein at least two light emitting regions are provided on the substrate, at least two light emitting units are disposed in each light emitting region, the first conductive structure comprises a plurality of electrode cables, the first conductive structure also comprises at least two light emitting unit cables which are in a one-to-one correspondence with the at least two light emitting regions, each light emitting unit cable is configured to connect light emitting units in a corresponding light emitting region, and
sequentially forming, on the substrate, a first conductive structure, a plurality of light emitting units, and a second conductive structure which are stacked comprises:
forming the at least two light emitting unit cables and the electrode cables of the first conductive structure on the substrate by a patterning process; and
sequentially forming, on the first conductive structure, the plurality of light emitting units and the second conductive structure which are stacked.

15. The method according to claim 13, wherein sequentially forming, on the substrate, a first conductive structure, a plurality of light emitting units, and a second conductive structure which are stacked comprises:
sequentially forming, on the substrate, the first conductive structure and the plurality of light emitting units which are stacked; and
sequentially forming, on the plurality of light emitting units, an insulating layer and the second conductive structure which are stacked.

16. The method according to claim 14, wherein sequentially forming, on the substrate, a first conductive structure, a plurality of light emitting units, and a second conductive structure which are stacked comprises:
sequentially forming, on the substrate, the first conductive structure, an insulating layer, a reflective layer, the plurality of light emitting units and the second conductive structure which are stacked.

17. A display apparatus, wherein the display apparatus comprises a display panel and a backlight source, and the backlight source comprises a substrate, and a first conductive structure, a plurality of light emitting units and a second conductive structure which are stacked on the substrate, wherein the first conductive structure and the second conductive structure are respectively on two sides of the plurality of light emitting units in a direction perpendicular to the substrate, and the first conductive structure and the second conductive structure are configured to load a voltage for the plurality of light emitting units.

18. The display apparatus according to claim 17, wherein one of the first conductive structure and the second conductive structure is a conductive layer.

19. The display apparatus according to claim 17, wherein at least two light emitting regions are provided on the substrate, and at least two light emitting units are disposed in each light emitting region; and
the first conductive structure comprises at least two light emitting unit cables which are in a one-to-one correspondence with the at least two light emitting regions, and each light emitting unit cable is configured to connect light emitting units in a corresponding light emitting region.

20. The display apparatus according to claim 19, wherein at least a part of at least one of the first conductive structure and the second conductive structure is out of the light emitting regions.
